(19) United States
(12) Patent Application Publication
(10) Pub. No.: US 2026/0150373 A1
(43) Pub. Date: May 28, 2026

(54) SEMICONDUCTOR DEVICE

(71) Applicant: Mitsubishi Electric Corporation, Tokyo (JP)

(72) Inventors: Kohei SAKO, Tokyo (JP); Taro MORIYA, Tokyo (JP); Kazuya KONISHI, Tokyo (JP)

(73) Assignee: Mitsubishi Electric Corporation, Tokyo (JP)

(21) Appl. No.: 19/337,831

(22) Filed: Sep. 23, 2025

(30) Foreign Application Priority Data
Nov. 28, 2024 (JP) 2024-206884

(51) Int. Cl. H10D 64/27

(52) U.S. Cl. CPC H10D 64/513

(57) ABSTRACT

An upper-stage electrode includes an upper-stage base portion and an upper-stage projection. The upper-stage base portion and the upper-stage projection of the upper-stage electrode form a convex shape protruding toward a second main surface. An oxide film includes a lower-stage oxide film formed on a side surface of a trench, in contact with a lower-stage electrode, an upper-stage oxide film formed on the side surface of the trench, in contact with the upper-stage base portion, a projection oxide film formed on the side surface of the trench, in contact with the upper-stage projection, and a boundary oxide film formed between the upper-stage electrode and the lower-stage electrode. The projection oxide film has a thickness greater than a thickness of the lower-stage oxide film.

### BACKGROUND

### Technical Field

The present disclosure relates to a semiconductor device, and particularly to a semiconductor device having a trench electrode.

### Description of the Background Art

FIG. 16 in Japanese Patent Application Laid-Open No. 2020-077727 discloses a semiconductor device for reducing a gate-collector capacitance Cgc and for reducing a switching loss, by providing a trench electrode with a two-staged structure including an upper-stage electrode and an embedded electrode (lower-stage electrode).

In the semiconductor device illustrated in FIG. 16 in Japanese Patent Application Laid-Open No. 2020-077727, because the upper-stage electrode has a projecting portion projecting toward the lower-stage electrode, there has been a problem that an electric field concentrates at the projecting portion, and such concentration of the electric field causes an increase in the gate leakage, and deteriorates the gate breakdown voltage.

### SUMMARY

An object of the present disclosure is to improve the gate breakdown voltage of a semiconductor device with a trench electrode having a two-staged structure.

A semiconductor device according to the present disclosure includes a semiconductor substrate, a drift layer, a base layer, a trench, an oxide film, and a trench electrode. The semiconductor substrate has a first main surface and a second main surface that is on the opposite side of the first main surface. The drift layer is provided on the semiconductor substrate. The drift layer has a first conductivity type, as the conductivity type thereof. The base layer is provided on the first main surface side of the drift layer. The base layer has a second conductivity type, as the conductivity type thereof. The trench is provided in a manner penetrating the base layer from the first main surface, and reaching the drift layer. The oxide film is provided in a manner covering the inner surface of the trench. The trench electrode is embedded in the trench, with the oxide film interposed between the trench electrode and the trench. The trench electrode includes a lower-stage electrode and an upper-stage electrode. The upper-stage electrode is provided nearer to the first main surface than the lower-stage electrode. The upper-stage electrode includes an upper-stage base portion and an upper-stage projection. The upper-stage projection projects toward the side of the second main surface, from the bottom surface that is a surface of the upper-stage base portion on a second main surface side. The upper-stage base portion and the upper-stage projection of the upper-stage electrode form a convex shape protruding toward the second main surface. The oxide film includes a lower-stage oxide film, an upper-stage oxide film, a projection oxide film, and a boundary oxide film. The lower-stage oxide film is formed on the side surface of the trench, and in contact with the lower-stage electrode. The upper-stage oxide film is formed on the side surface of the trench, and in contact with the upper-stage base portion. The projection oxide film is formed on the side surface of the trench, and in contact with the upper-stage projection. The boundary oxide film is formed between the upper-stage electrode and the lower-stage electrode. The projection oxide film has a thickness t2 greater than a thickness t1 of the lower-stage oxide film.

With the semiconductor device according to the present disclosure, because the thickness t2 of the projection oxide film is greater than the thickness t1 of the lower-stage oxide film, it is possible to reduce a surface area of the upper-stage projection, the surface area being an area facing the lower-stage electrode. As a result, the effect of improving the gate breakdown voltage can be achieved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is an enlarged cross-sectional view of a relevant part of the semiconductor device according to the first preferred embodiment, illustrating the shape of the bottom surface of an upper-stage electrode;

FIG. 3 is a cross-sectional view of a semiconductor device according to a first modification of the first preferred embodiment;

FIG. 4 is a cross-sectional view of a semiconductor device according to a second modification of the first preferred embodiment;

FIG. 5 is a cross-sectional view of a semiconductor device according to a third modification of the first preferred embodiment;

FIG. 6 is a cross-sectional view of a semiconductor device according to a fourth modification of the first preferred embodiment;

FIG. 7 is a cross-sectional view of a semiconductor device according to a fifth modification of the first preferred embodiment;

FIG. 8 is a cross-sectional view of a semiconductor device according to a sixth modification of the first preferred embodiment; and

FIG. 9 is a cross-sectional view of a semiconductor device according to a seventh modification of the first preferred embodiment.

### DESCRIPTION OF THE PREFERRED EMBODIMENTS

A first conductivity type will be described as the N-type, and a second conductivity type will be described as the P-type, but these conductivity types may also be reversed. In other words, the first conductivity type may be the P-type, and the second conductivity type may be the N-type.

### A. First Preferred Embodiment

### <A-1. Configuration>

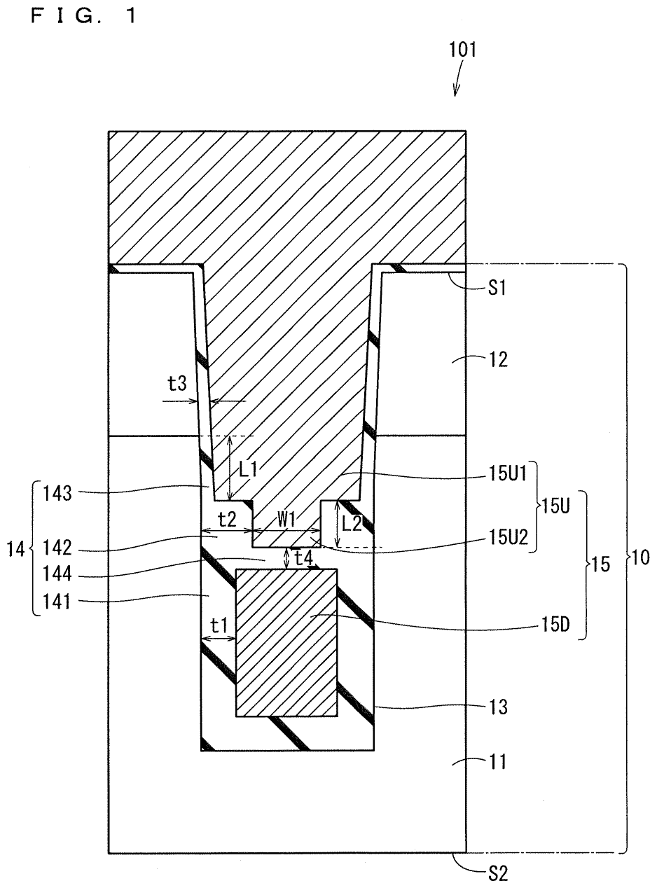

FIG. 1 is a cross-sectional view of a semiconductor device 101 according to a first preferred embodiment. The semiconductor device 101 is a transistor having an insulated gate, such as an insulated gate bipolar transistor (IGBT) or a metal-oxide-semiconductor field-effect transistor (MOSFET). The semiconductor device 101 includes a semiconductor substrate 10 having a first main surface S1 and a second main surface S2 that is a main surface that is on the opposite side of the first main surface S1. The first main surface S1 is an upper main surface of the semiconductor substrate 10 in FIG. 1, and the second main surface S2 is a lower main surface of the semiconductor substrate 10 in FIG. 1.

An N-type drift layer 11 is formed on the semiconductor substrate 10. A P-type base layer 12 is formed on the drift layer 11 on the side of the first main surface S1. A trench 13 is formed in a manner penetrating the base layer 12 from the first main surface S1.

The inner surface of the trench 13 is covered with an oxide film 14. A trench electrode 15 is embedded in the trench 13, with the oxide film 14 interposed therebetween.

The trench electrode 15 includes a lower-stage electrode 15D and an upper-stage electrode 15U that is provided on the side nearer to the first main surface S1 than the lower-stage electrode 15D.

The upper-stage electrode 15U includes an upper-stage base portion 15U1 and an upper-stage projection 15U2 projecting from the bottom surface of the upper-stage base portion 15U1 toward the second main surface S2, the bottom surface being a surface on the side nearer to the second main surface S2. The upper-stage base portion 15U1 and the upper-stage projection 15U2 of the upper-stage electrode 15U form a convex shape protruding toward the second main surface S2.

The oxide film 14 includes a lower-stage oxide film 141 formed on the side surface of the trench 13, in contact with the lower-stage electrode 15D, a projection oxide film 142 formed on the side surface of the trench 13, in contact with the upper-stage projection 15U2, an upper-stage oxide film 143 formed on the side surface of the trench 13, in contact with the upper-stage base portion 15U1, and a boundary oxide film 144 formed between the lower-stage electrode 15D and the upper-stage electrode 15U.

The lower-stage oxide film 141 has a thickness t1 smaller than the thickness t2 of the projection oxide film 142. By setting t1<t2, it is possible to reduce a surface area of the upper-stage projection 15U2, the surface area being an area facing the lower-stage electrode 15D. As a result, the effect of improving the gate breakdown voltage can be achieved.

In FIG. 1, the lower-stage oxide film 141 has a thickness t1 greater than the thickness t3 of the upper-stage oxide film 143. In other words, t3<t1<t2 is established. By forming the lower-stage oxide film 141 thick, it becomes easier to form a thick projection oxide film 142 in a subsequent process. For this reason, in FIG. 1, t3<t1<t2 is used. Without the consideration to the process described above, t1<t3<t2 may also be used.

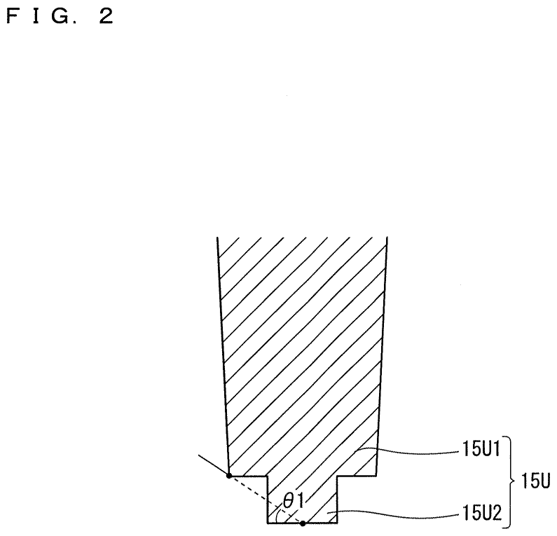

FIG. 2 illustrates an angle θ1 formed by a line connecting the center of the bottom end of the upper-stage projection 15U2 and the bottom end of the side surface of the upper-stage base portion 15U1, with the horizontal direction. As illustrated in FIG. 1, by setting t3<t2, 0°<θ1<90° is established. As a result, the sharpness of the bottom surface of the upper-stage electrode 15U can be mitigated, and the effect of improving the gate breakdown voltage can be achieved. As θ1 is increased, the effect of improving the gate breakdown voltage is also increased. For this reason, preferably, 15°<θ1<90°, and more preferably 30°<θ1<90°.

As illustrated in FIG. 1, the length L1 between the base layer 12 and the bottom end of the side surface of the upper-stage base portion 15U1 is greater than the projection length L2 of the upper-stage projection 15U2 from the upper-stage base portion 15U1. The projection length L2 of the upper-stage projection 15U2 is defined as a length from the deepest part of the upper-stage base portion 15U1 to the deepest part of the upper-stage projection 15U2. In other words, the projection length L2 of the upper-stage projection 15U2 from the upper-stage base portion 15U1 is shorter than the length L1 between the base layer 12 and the bottom end of the side surface of the upper-stage base portion 15U1. With this, it is possible to increase the area by which the drift layer 11 is in contact with the upper-stage oxide film 143 that is thin. Because electrons are allowed to concentrate in this area, and an electron injection path with a low resistance can be formed, the ON-voltage is reduced.

As illustrated in FIG. 1, the width w1 of the upper-stage projection 15U2 is set greater than the projection length L2 of the upper-stage projection 15U2. With L2<w1, because the aspect ratio (L2/w1) of the upper-stage projection 15U2 is reduced, embedding capability of the upper-stage projection 15U2 is improved.

As illustrated in FIG. 1, the thickness t4 of the boundary oxide film 144 is set greater than the thickness t3 of the projection oxide film. In this manner, because the distance between the upper-stage projection 15U2 and the lower-stage electrode 15D is increased, the electric field therebetween is relieved.

As illustrated in FIG. 1, in the semiconductor device 101, the upper-stage projection 15U2 has a flat bottom surface. As a result, the amount of recess formed that occurs in the upper portion of the upper-stage electrode 15U during embedding is reduced. Therefore, it is possible to ensure the flatness of the surface of an interlayer insulating film or an emitter electrode that is formed on the upper-stage electrode 15U. In this manner, the assemblability is improved, and the risk of wire peeling is reduced.

### <A-2. Modifications>

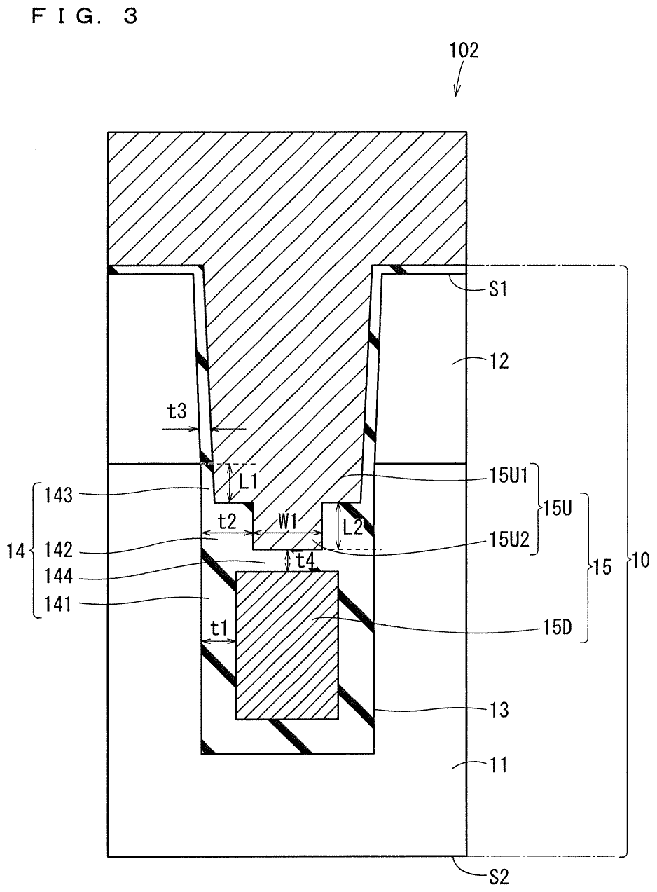

FIG. 3 is a cross-sectional view of a semiconductor device 102 according to a first modification of the first preferred embodiment. While L2<L1 in the semiconductor device 101, in the semiconductor device 102, L1<L2. With this, the length between the side surface of the upper-stage electrode 15U and the lower-stage electrode 15D is increased, so that the electric field between the upper-stage electrode 15U and the lower-stage electrode 15D is relieved.

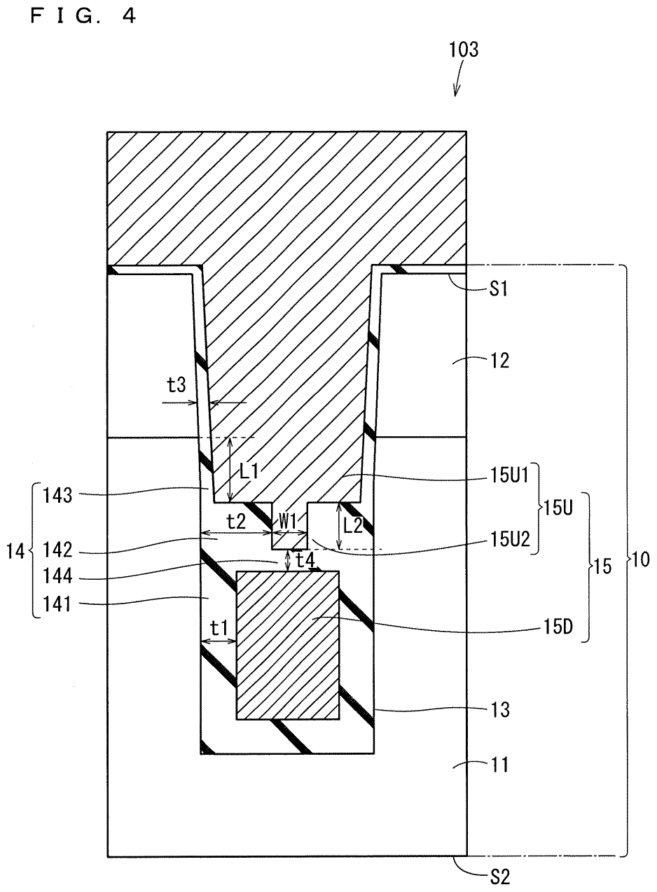

FIG. 4 is a cross-sectional view of a semiconductor device 103 according to a second modification of the first preferred embodiment. While L2<w1 in the semiconductor device 101, in the semiconductor device 103, w1<L2. With this, the surface area of the upper-stage projection 15U2, the surface area being an area facing the lower-stage electrode 15D, is reduced. With this, the gate breakdown voltage is improved.

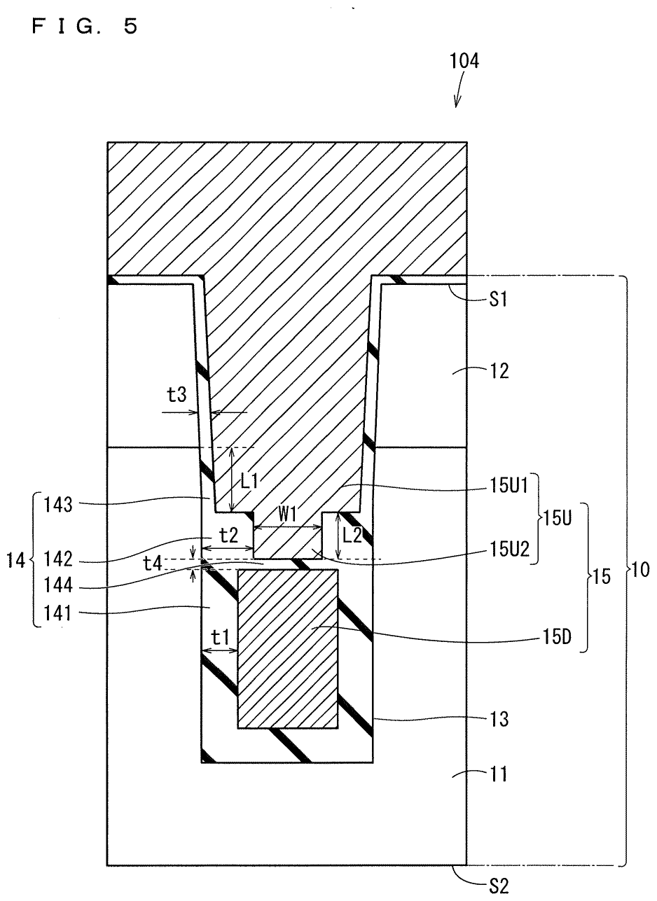

FIG. 5 is a cross-sectional view of a semiconductor device 104 according to a third modification of the first preferred embodiment. While t3<t4 in the semiconductor device 101, in the semiconductor device 104, t4<t3. By setting t4<t3, the following advantageous effects can be achieved, in a configuration in which the upper-stage electrode 15U is a gate electrode and the lower-stage electrode 15D is an emitter electrode. With smaller t4, the gate-emitter capacitance Cge between the upper-stage electrode 15U and the lower-stage electrode 15D is increased. Furthermore, with larger t3, the gate-collector capacitance Cgc is reduced. Therefore, by setting t4<t3, it is possible to achieve a lower gate capacitance ratio Cgc/Cge, which has a correlation with electromagnetic noise. As a result, the switching waveform can be optimized, and the trade-off between the turn-on loss and the electromagnetic noise can be mitigated.

In addition, by setting t4<t3 regardless of the potentials to which the upper-stage electrode 15U and the lower-stage electrode 15D are set, the following advantageous effect can be achieved. By reducing the thickness of the boundary oxide film 144, the areas of the upper-stage electrode 15U and the lower-stage electrode 15D can be increased. Therefore, wiring resistance can be reduced. As a result, the switching loss can be reduced.

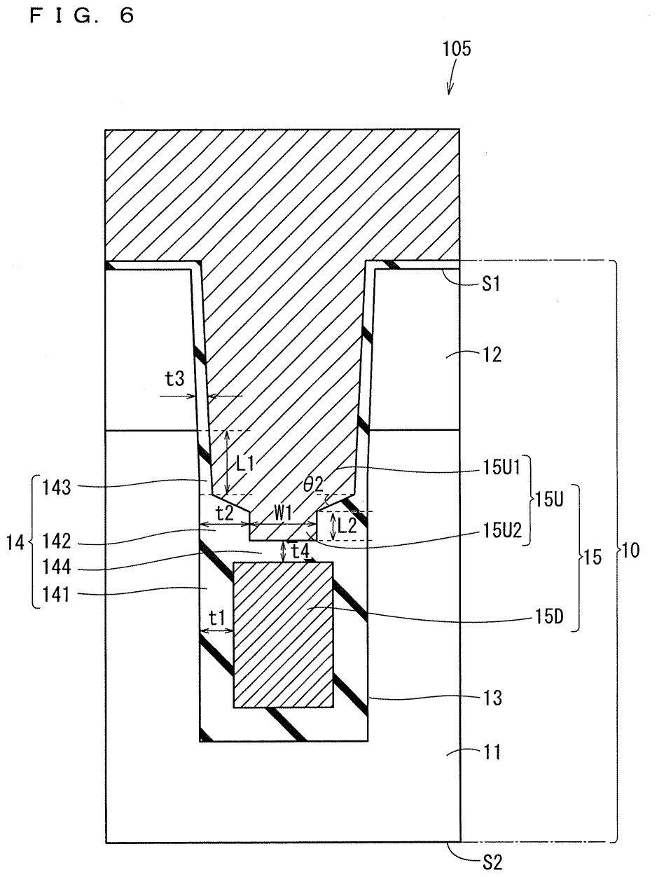

FIG. 6 is a cross-sectional view of a semiconductor device 105 according to a fourth modification of the first preferred embodiment. In the semiconductor device 101, the upper-stage base portion 1 5U1 has a flat bottom surface. By contrast, the bottom surface of the upper-stage base portion 1 5U1 in the semiconductor device 105 is inclined in a manner extending deeper from the side surface of the upper-stage electrode 15U toward the upper-stage projection 15U 2. Denoting the inclination angle as θ2, 0°<θ2<90°. Preferably, 15° <θ2<90°. More preferably, 30°<θ2<90°. As a result, the sharpness of the upper-stage electrode 15U facing the lower-stage electrode 15D is alleviated, and the gate breakdown voltage is improved. As θ2 is increased, the effect of improving the gate breakdown voltage is increased further. Therefore, preferably, 15°<θ2<90°, and more preferably, 30°<θ2<90°.

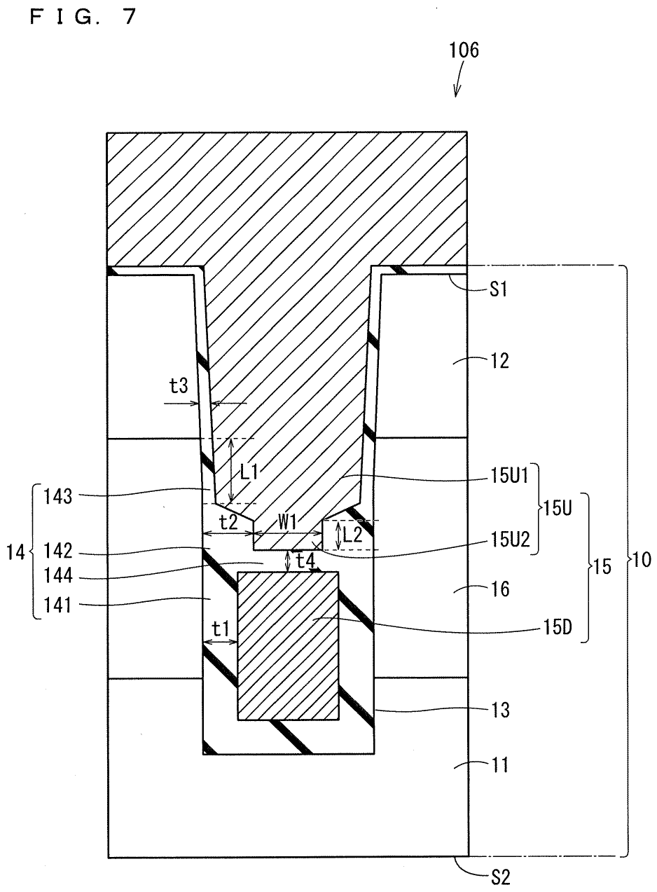

FIG. 7 is a cross-sectional view of a semiconductor device 106 according to a fifth modification of the first preferred embodiment. The semiconductor device 106 is different from the semiconductor device 105 only in that a carrier accumulation layer (CS layer) 16 of the first conductivity type is provided between the drift layer 11 and the base layer 12. In the semiconductor device 105, because the bottom end of the side surface of the upper-stage electrode 15U is not sharp, it is difficult to form an N-type inversion layer in the drift layer 11 around the upper-stage electrode, and the amount of electron injection becomes reduced. This phenomenon is prominent on the side part of the boundary oxide film 144 where the sharp part has extended. Because the semiconductor device 106 includes the CS layer 16, the amount of electron injection is increased, and therefore, an increase in the ON-voltage is suppressed.

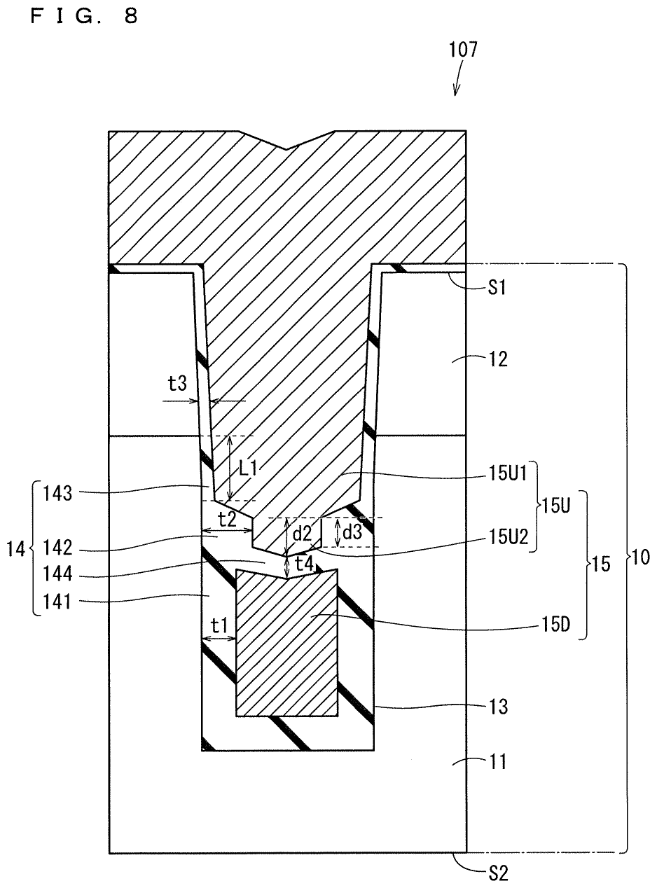

FIG. 8 is a cross-sectional view of a semiconductor device 107 according to a sixth modification of the first preferred embodiment. In the semiconductor device 101, the upper-stage projection 15U2 has a flat bottom surface. By contrast, in the semiconductor device 107, the upper-stage projection 15U2 has an inclined bottom surface the center of which is at its deepest, and that becomes shallower toward the bottom surface of the upper-stage base portion 15U1. Denoting the depth of the center of the upper-stage projection 15U2 as d2, and denoting the depth of the side surface of the upper-stage projection 15U2 as d3, d3<d2 is established. d2 herein is defined as the distance between the deepest part of the upper-stage base portion 15U1 and the bottom surface at the center of the upper-stage projection 15U2. d3 is defined as the distance between the deepest part of the upper-stage base portion 15U1 and the bottom surface of the side surface of the upper-stage projection 15U2. Because the bottom surface at the center of the upper-stage projection 15U2 is the deepest part of the upper-stage projection 15U2, the depth d2 of the center of the upper-stage projection 15U2 is equal to the projection length L2 of the upper-stage projection 15U2. By setting d3<d2, the embeddability of the upper-stage projection 15U2 is improved, and the electric field between the upper-stage projection 15U2 and the lower-stage electrode 15D is suppressed from locally intensifying.

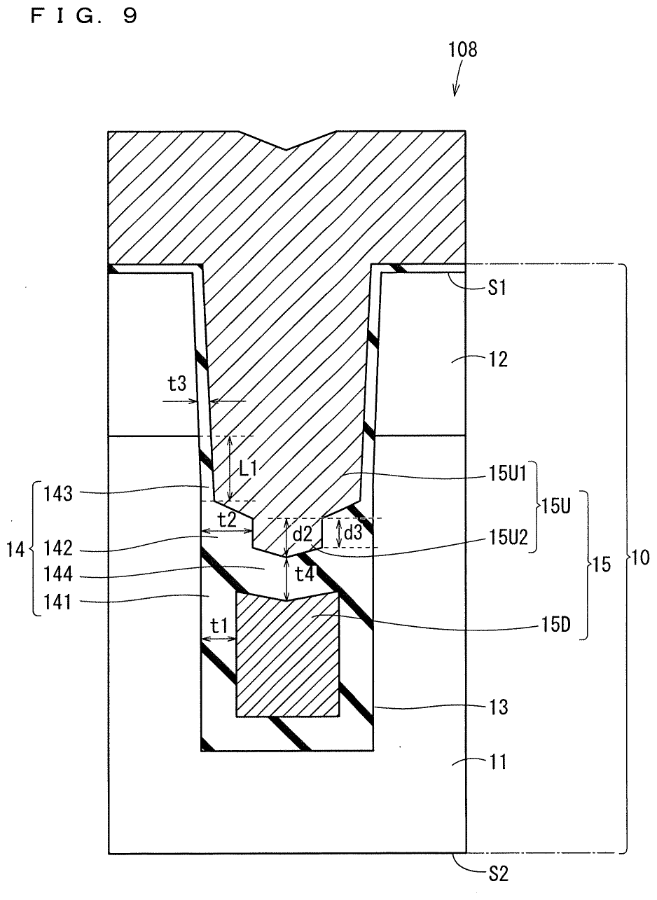

FIG. 9 is a cross-sectional view of a semiconductor device 108 according to a seventh modification of the first preferred embodiment. In the semiconductor device 101, because t1>t4, the areas of the upper-stage electrode 15U and the lower-stage electrode 15D can be increased, so that wiring resistance can be reduced. Consequently, the switching loss is reduced. By contrast, in the semiconductor device 108, t1<t4. With this, an insulating distance can be ensured between the upper-stage electrode 15U and the lower-stage electrode 15D. As a result, the effect of improving the gate breakdown voltage can be achieved.

### <A-3. Potential of Trench Electrode 15>

In the semiconductor device 101 to 107, either one of the upper-stage electrode 15U and the lower-stage electrode 15D may be a gate electrode, and the other may be an emitter electrode. With such a configuration, Cgc is reduced, and high-speed switching can be achieved. When the upper-stage electrode 15U is used as an emitter electrode and the lower-stage electrode is used as a gate electrode, Cgc is increased, and recovery dV/dt, which can be a cause of noise, can be reduced.

It is also possible to use both of the upper-stage electrode 15U and the lower-stage electrode 15D as gate electrodes. With such a configuration, because the boundary oxide film 144 is provided between the upper-stage electrode 15U and the lower-stage electrode 15D, Cgc can be reduced by that amount, and high-speed switching can be achieved, compared with the single-staged gate structure.

It is also possible to use one of the upper-stage electrode 15U and the lower-stage electrode 15D as a gate electrode, and the other as a control gate electrode. With such a configuration, the ratio between the gate capacitance and the control gate capacitance can be optimized, and high-speed switching can be achieved. When the upper-stage electrode 15U is used as a control gate electrode, Cge can be reduced. When the lower-stage electrode 15D is used as a control gate electrode, Cgc can be reduced.

Although the preferred embodiment and the like have been described in detail, the present invention is not limited to such preferred embodiment and the like, and various modifications and replacements may be made to the preferred embodiment and the like, within the scope not departing from the scope as stipulated in the claims.

Various aspects of the present disclosure will be summarized below as Appendices.

### (Appendix 1)

A semiconductor device comprising:
a semiconductor substrate that has a first main surface and a second main surface that is a main surface on an opposite side of the first main surface;
a drift layer that is of a first conductivity type and is formed on the semiconductor substrate;
a base layer that is of a second conductivity type and that is formed on a first main surface side of the drift layer;
a trench that penetrates the base layer from the first main surface and that reaches the drift layer;
an oxide film that covers an inner surface of the trench; and
a trench electrode that is embedded in the trench, with the oxide film interposed between the trench electrode and the trench,
wherein
the trench electrode includes:
   a lower-stage electrode; and
   an upper-stage electrode formed nearer to the first main surface than the lower-stage electrode,
the upper-stage electrode includes:
   an upper-stage base portion; and
   an upper-stage projection projecting toward the second main surface from a bottom surface that is a surface of the upper-stage base portion on a second main surface side,
   with the upper-stage base portion and the upper-stage projection forming a convex shape protruding toward the second main surface,
the oxide film includes:
   a lower-stage oxide film that is formed on a side surface of the trench, and in contact with the lower-stage electrode;
   an upper-stage oxide film that is formed on a side surface of the trench, and in contact with the upper-stage base portion;
   a projection oxide film that is formed on the side surface of the trench, and in contact with the upper-stage projection; and
   a boundary oxide film that is formed between the upper-stage electrode and the lower-stage electrode, and
the projection oxide film has a thickness t2 greater than a thickness t1 of the lower-stage oxide film.

### (Appendix 2)

The semiconductor device according to Appendix 1, wherein, denoting an angle formed by a line connecting a center of a bottom end of the upper-stage projection and a bottom end of a side surface of the upper-stage base portion, with a horizontal direction, as θ1, 0°<θ1<90°.

### (Appendix 3)

The semiconductor device according to Appendix 1 or 2, wherein
a bottom end of the upper-stage projection is positioned below a deepest part of the base layer, and
a distance L1 between a deepest part of the base layer and a bottom end of a side surface of the upper-stage base portion is smaller than a projection length L2 of the upper-stage projection.

### (Appendix 4)

The semiconductor device according to Appendix 1 or 2, wherein
a bottom end of the upper-stage projection is positioned below a deepest part of the base layer, and
a distance L1 between a deepest part of the base layer and a bottom end of the upper-stage projection is greater than a projection length L2 of the upper-stage projection.

### (Appendix 5)

The semiconductor device according to any one of Appendices 1 to 4, wherein the upper-stage projection has a width w1 greater than a projection length L2 of the upper-stage projection.

### (Appendix 6)

The semiconductor device according to any one of Appendices 1 to 4, wherein the upper-stage projection has a width w1 smaller than a projection length L2 of the upper-stage projection.

### (Appendix 7)

The semiconductor device according to any one of Appendices 1 to 6, wherein the boundary oxide film has a thickness t4 smaller than a thickness t3 of the projection oxide film.

### (Appendix 8)

The semiconductor device according to any one of Appendices 1 to 6, wherein the boundary oxide film has a thickness t4 greater than a thickness t3 of the projection oxide film.

### (Appendix 9)

The semiconductor device according to any one of Appendices 1 to 8, wherein, denoting an angle formed by the bottom surface of the upper-stage base portion in contact with the projection oxide film, with a horizontal direction, as θ2, 0°<θ2<90°.

### (Appendix 10)

The semiconductor device according to any one of Appendices 1 to 9, further comprising a carrier accumulation layer that is of a first conductivity type and that is formed between the drift layer and the base layer.

### (Appendix 11)

The semiconductor device according to any one of Appendices 1 to 10, wherein a center of the upper-stage projection is at a depth d2 that is deeper than a depth d3 of an end of the upper-stage projection.

### (Appendix 12)

The semiconductor device according to any one of Appendices 1 to 10, wherein the upper-stage projection has a flat bottom surface.

### (Appendix 13)

The semiconductor device according to any one of Appendices 1 to 12, wherein the boundary oxide film has a thickness t4 smaller than a thickness t1 of the lower-stage oxide film.

### (Appendix 14)

The semiconductor device according to any one of Appendices 1 to 12, wherein the boundary oxide film has a thickness t4 greater than a thickness t1 of the lower-stage oxide film.

### (Appendix 15)

The semiconductor device according to any one of Appendices 1 to 12, wherein one of the upper-stage electrode and the lower-stage electrode is a gate electrode, and remaining one is a gate electrode, an emitter electrode, or a control gate electrode.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate that has a first main surface and a second main surface that is a main surface on an opposite side of the first main surface;
a drift layer that is of a first conductivity type and is formed on the semiconductor substrate;
a base layer that is of a second conductivity type and that is formed on a first main surface side of the drift layer;
a trench that penetrates the base layer from the first main surface and that reaches the drift layer;
an oxide film that covers an inner surface of the trench; and
a trench electrode that is embedded in the trench, with the oxide film interposed between the trench electrode and the trench,
wherein the trench electrode includes:
a lower-stage electrode; and
an upper-stage electrode formed nearer to the first main surface than the lower-stage electrode,
the upper-stage electrode includes:
an upper-stage base portion; and
an upper-stage projection projecting toward the second main surface from a bottom surface that is a surface of the upper-stage base portion on the second main surface side,
with the upper-stage base portion and the upper-stage projection forming a convex shape protruding toward the second main surface,
the oxide film includes:
a lower-stage oxide film that is formed on a side surface of the trench, and in contact with the lower-stage electrode;
an upper-stage oxide film that is formed on a side surface of the trench, and in contact with the upper-stage base portion;
a projection oxide film that is formed on the side surface of the trench, and in contact with the upper-stage projection; and
a boundary oxide film that is formed between the upper-stage electrode and the lower-stage electrode, and
the projection oxide film has a thickness t2 greater than a thickness t1 of the lower-stage oxide film.

2. The semiconductor device according to claim 1, wherein, denoting an angle formed by a line connecting a center of a bottom end of the upper-stage projection and a bottom end of a side surface of the upper-stage base portion with a horizontal direction as θ1, 0°<θ1<90°.

3. The semiconductor device according to claim 1, wherein
a bottom end of the upper-stage projection is positioned below a deepest part of the base layer, and
a distance L1 from a deepest part of the base layer to a bottom end of a side surface of the upper-stage base portion is smaller than a projection length L2 of the upper-stage projection.

4. The semiconductor device according to claim 1, wherein
a bottom end of the upper-stage projection is positioned below a deepest part of the base layer, and
a distance L1 from a deepest part of the base layer to a bottom end of the upper-stage projection is greater than a projection length L2 of the upper-stage projection.

5. The semiconductor device according to claim 1, wherein the upper-stage projection has a width w1 greater than a projection length L2 of the upper-stage projection.

6. The semiconductor device according to claim 1, wherein the upper-stage projection has a width w1 smaller than a projection length L2 of the upper-stage projection.

7. The semiconductor device according to claim 1, wherein the boundary oxide film has a thickness t4 smaller than a thickness t3 of the projection oxide film.

8. The semiconductor device according to claim 1, wherein the boundary oxide film has a thickness t4 greater than a thickness t3 of the projection oxide film.

9. The semiconductor device according to claim 1, wherein, denoting an angle formed by the bottom surface of the upper-stage base portion in contact with the projection oxide film with a horizontal direction as θ2, 0°<θ2<90°.

10. The semiconductor device according to claim 1, further comprising a carrier accumulation layer that is of a first conductivity type and that is formed between the drift layer and the base layer.

11. The semiconductor device according to claim 1, wherein a center of the upper-stage projection is at a depth d2 that is deeper than a depth d3 of a periphery of the upper-stage projection.

12. The semiconductor device according to claim 1, wherein the upper-stage projection has a flat bottom surface.

13. The semiconductor device according to claim 1, wherein the boundary oxide film has a thickness t4 smaller than a thickness t1 of the lower-stage oxide film.

14. The semiconductor device according to claim 1, wherein the boundary oxide film has a thickness t4 greater than a thickness t1 of the lower-stage oxide film.

15. The semiconductor device according to claim 1, wherein one of the upper-stage electrode and the lower-stage electrode is a gate electrode, and remaining one is a gate electrode, an emitter electrode, or a control gate electrode.
